(19) United States
(12) Patent Application Publication
(10) Pub. No.: US 2019/0074383 A1
(43) Pub. Date: Mar. 7, 2019

(54) THIN FILM TRANSISTOR STRUCTURE AND DRIVING CIRCUIT OF AMOLED

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Mingjue YU, Shenzhen (CN); Yuan-jun HSU, Shenzhen (CN)

(21) Appl. No.: 15/577,461

(22) PCT Filed: Nov. 6, 2017
(86) PCT No.: PCT/CN2017/109494

§ 371 Date: Nov. 28, 2017

(30) Foreign Application Priority Data
Sep. 4, 2017 (CN) 201710784792.X

(51) Int. Cl. H01L 29/786; G09G 3/3225

(52) U.S. Cl. CPC H01L 29/78633; H01L 29/7869; H01L 29/4908; G09G 3/3225; H01L 29/78618

(57) ABSTRACT

A thin film transistor structure is provided with a glass substrate, a buffer layer, a metal oxide semiconductor layer, and a gate metal layer. A shielding metal layer is disposed between the glass substrate and the buffer layer. A projection area of the gate metal layer on a plane of the glass substrate aligns to a projection area of the shielding metal layer on the plane, the projection area of the shielding metal layer on the plane of the glass substrate covers the projection area of the metal oxide semiconductor layer of the channel area on the plane of the glass substrate.

### FIELD OF INVENTION

The present invention relates to a display technology, and more particularly to a thin film transistor structure and a driving circuit of an AMOLED.

### BACKGROUND OF INVENTION

With the development of science and technology, AMOLED (active-matrix organic light emitting diode) display devices are more and more popular. Current AMOLED display devices generally use a 3T1C AMOLED driving circuit, which is constituted by three thin film transistors and one capacitor.

Impact of the emitting light and external light will drive a thin film transistor in the AMOLED driving circuit to become unstable, such that is affects display quality of the AMOLED display devices.

It is therefore necessary to provide a thin film transistor structure and a driving circuit of an AMOLED, in order to solve problems existing in conventional technology as described above.

### SUMMARY OF INVENTION

An object of the present invention is to provide a thin film transistor structure and a driving circuit of an active-matrix organic light emitting diode (AMOLED) for promoting a working stability of a thin film transistor to improve a display quality of an AMOLED display device, in order to solve a problem of a poor working stability of a conventional thin film transistor and a driving circuit of an AMOLED having the thin film transistor.

One embodiment of the present invention provides a thin film transistor structure, comprising:

a glass substrate,

a buffer layer disposed on the glass substrate;

a metal oxide semiconductor layer disposed on the buffer layer, and defining a position of an active drive area of the thin film transistor structure through the metal oxide semiconductor layer, and the metal oxide semiconductor layer comprising a source electrode area, a drain electrode area, and a channel area;

a gate insulating layer disposed on the metal oxide semiconductor layer to separate the metal oxide semiconductor layer from a gate metal layer;

wherein the gate metal layer is disposed on the gate insulating layer;

an interlayer insulating layer disposed on the gate metal layer for performing a planarization treatment on the glass substrate having the gate metal layer, wherein the interlayer insulating layer has a source contact hole and a drain contact hole therein;

a source metal layer disposed on the interlayer insulating layer, and configured to connect with the source electrode area of the metal oxide semiconductor layer through the source contact hole;

a drain metal layer disposed on the interlayer insulating layer, and configured to connect with the drain electrode area of the metal oxide semiconductor layer through the drain contact hole; and

a protective layer disposed on the interlayer insulating layer having the source metal layer and the drain metal layer;

wherein a shielding metal layer is disposed between the glass substrate and the buffer layer, and a projection area of the gate metal layer on a plane of the glass substrate aligns to a projection area of the shielding metal layer on the plane, the projection area of the shielding metal layer on the plane of the glass substrate covers a projection area of the metal oxide semiconductor layer of the channel area on the plane of the glass substrate.

In the thin film transistor structure of the present invention, the buffer layer has a thickness above 4000 Å.

In the thin film transistor structure of the present invention, the shielding metal layer is a molybdenum metal layer, an aluminum metal layer, or a copper metal layer;

the buffer layer is a silica buffer layer;

the metal oxide semiconductor layer is an indium gallium zinc oxide metal oxide semiconductor layer or an indium tin zinc oxide metal oxide semiconductor layer;

the gate insulating layer is a silicon nitride layer or a silica layer;

the gate metal layer is a molybdenum metal layer, an aluminum metal layer, or a copper metal layer;

the source metal layer is a molybdenum metal layer, an aluminum metal layer, or a copper metal layer;

the drain metal layer is a molybdenum metal layer, an aluminum metal layer, or a copper metal layer;

the interlayer insulating layer is a silicon nitride layer or a silica layer; and

the protective layer is a silicon nitride layer or a silica layer.

In the thin film transistor structure of the present invention, the gate insulating layer is a single layer of silicon nitride, a single layer of silica, a double layer of silicon nitride, or a double layer of silica.

A further embodiment of the present invention provides a thin film transistor structure, comprising:

a glass substrate;

a buffer layer disposed on the glass substrate;

a metal oxide semiconductor layer disposed on the buffer layer, and configured to define a position of an active drive area of the thin film transistor structure through the metal oxide semiconductor layer, wherein the metal oxide semiconductor layer comprises a source electrode area, a drain electrode area, and a channel area;

a gate insulating layer disposed on the metal oxide semiconductor layer to separate the metal oxide semiconductor layer from a gate metal layer;

wherein the gate metal layer is disposed on the gate insulating layer;

an interlayer insulating layer disposed on the gate metal layer for performing a planarization treatment on the glass substrate having the gate metal layer, wherein the interlayer insulating layer has a source contact hole and a drain contact hole therein;

a source metal layer disposed on the interlayer insulating layer, and configured to connect with the source electrode area of the metal oxide semiconductor layer through the source contact hole;

a drain metal layer disposed on the interlayer insulating layer, and configured to connect with the drain electrode area of the metal oxide semiconductor layer through the drain contact hole; and

a protective layer disposed on the interlayer insulating layer having the source metal layer and the drain metal layer;

wherein a shielding metal layer is disposed between the glass substrate and the buffer layer, and a projection area of the shielding metal layer on a plane of the glass substrate covers a projection area of the metal oxide semiconductor layer on the plane of the glass substrate.

In the thin film transistor structure of the present invention, the interlayer insulating layer has a shielding metal layer contact hole passing through the interlayer insulating layer and the buffer layer, and the source metal layer connects with the shielding metal layer through the shielding metal layer contact hole.

In the thin film transistor structure of the present invention, the buffer layer has a thickness greater than 4000 Å.

In the thin film transistor structure of the present invention, the shielding metal layer is a molybdenum metal layer, an aluminum metal layer, or a copper metal layer;

the buffer layer is a silica buffer layer;

the metal oxide semiconductor layer is an indium gallium zinc oxide metal oxide semiconductor layer or an indium tin zinc oxide metal oxide semiconductor layer;

the gate insulating layer is a silicon nitride layer or a silica layer;

the gate metal layer is a molybdenum metal layer, an aluminum metal layer, or a copper metal layer;

the source metal layer is a molybdenum metal layer, an aluminum metal layer, or a copper metal layer;

the drain metal layer is a molybdenum metal layer, an aluminum metal layer, or a copper metal layer;

the interlayer insulating layer is a silicon nitride layer or a silica layer; and

the protective layer a silicon nitride layer or a silica layer.

In the thin film transistor structure of the present invention, the gate insulating layer is a single layer of silicon nitride, a single layer of silica, a double layer of silicon nitride, or a double layer of silica.

A further embodiment of the present invention provides an AMOLED driving circuit, comprising a first thin film transistor, a second thin film transistor, a third thin film transistor, a storage capacitor, and a light emitting diode;

wherein the first thin film transistor has an input end connecting with data lines, a control end connecting with scan lines, and an output end connecting with a control end of the second thin film transistor;

an input end of the second thin film transistor connects with a driving power, and an output end of the second thin film transistor connects with a positive electrode of the light emitting diode;

a negative electrode of the light emitting diode connects to the ground;

an input end of the third thin film transistor connects with the output end of the second thin film transistor, and output end of the third thin film transistor connects with an induced current check end;

one end of the storage capacitor connects with a control end of the second thin film transistor, another end of the storage capacitor connects with the output end of the second thin film transistor;

wherein each of the first thin film transistor and the third thin film transistor comprises:

a glass substrate;

a buffer layer disposed on the glass substrate;

a metal oxide semiconductor layer disposed on the buffer layer, and configured to define a position of an active drive area of the thin film transistor structure through the metal oxide semiconductor layer, wherein the metal oxide semiconductor layer comprises a source electrode area, a drain electrode area, and a channel area;

a gate insulating layer disposed on the metal oxide semiconductor layer to separate the metal oxide semiconductor layer from a gate metal layer;

wherein the gate metal layer is disposed on the gate insulating layer;

an interlayer insulating layer disposed on the gate metal layer for performing a planarization treatment on the glass substrate having the gate metal layer, wherein the interlayer insulating layer has a source contact hole and a drain contact hole therein;

a source metal layer disposed on the interlayer insulating layer, and configured to connect with the source electrode area of the metal oxide semiconductor layer through the source contact hole;

a drain metal layer disposed on the interlayer insulating layer, and configured to connect with the drain electrode area of the metal oxide semiconductor layer through the drain contact hole; and

a protective layer disposed on the interlayer insulating layer having the source metal layer and the drain metal layer;

wherein a shielding metal layer is disposed between the glass substrate and the buffer layer, and a projection area of the gate metal layer on a plane of the glass substrate aligns to a projection area of the shielding metal layer on the plane, the projection area of the shielding metal layer on the plane of the glass substrate covers a projection area of the metal oxide semiconductor layer of the channel area on the plane of the glass substrate;

the second thin film transistor comprises:

a glass substrate;

a buffer layer disposed on the glass substrate;

a metal oxide semiconductor layer disposed on the buffer layer, and configured to define a position of an active drive area of the thin film transistor structure through the metal oxide semiconductor layer, wherein the metal oxide semiconductor layer comprises a source electrode area, a drain electrode area, and a channel area;

a gate insulating layer disposed on the metal oxide semiconductor layer to separate the metal oxide semiconductor layer from a gate metal layer;

wherein the gate metal layer is disposed on the gate insulating layer;

an interlayer insulating layer disposed on the gate metal layer for performing a planarization treatment on the glass substrate having the gate metal layer, wherein the interlayer insulating layer has a source contact hole and a drain contact hole therein;

a source metal layer disposed on the interlayer insulating layer, and configured to connect with the source electrode area of the metal oxide semiconductor layer through the source contact hole;

a drain metal layer disposed on the interlayer insulating layer, and configured to connect with the drain electrode area of the metal oxide semiconductor layer through the drain contact hole; and

a protective layer disposed on the interlayer insulating layer having the source metal layer and the drain metal layer;

wherein a shielding metal layer is disposed between the glass substrate and the buffer layer, and a projection area of the shielding metal layer on the plane of the glass substrate covers a projection area of the metal oxide semiconductor layer of the channel area on the plane of the glass substrate.

In the AMOLED driving circuit of the present invention, the buffer layer has a thickness greater than 4000 Å.

In the AMOLED driving circuit of the present invention, the shielding metal layer is a molybdenum metal layer, an aluminum metal layer, or a copper metal layer;

the buffer layer is a silica buffer layer;

the metal oxide semiconductor layer is an indium gallium zinc oxide metal oxide semiconductor layer or an indium tin zinc oxide metal oxide semiconductor layer;

the gate insulating layer is a silicon nitride layer or a silica layer;

the gate metal layer is a molybdenum metal layer, an aluminum metal layer, or a copper metal layer;

the source metal layer is a molybdenum metal layer, an aluminum metal layer, or a copper metal layer;

the drain metal layer is a molybdenum metal layer, an aluminum metal layer, or a copper metal layer;

the interlayer insulating layer is a silicon nitride layer or a silica layer; and

the protective layer is a silicon nitride layer or a silica layer.

In the AMOLED driving circuit of the present invention, the gate insulating layer is a single layer of silicon nitride, a single layer of silica, a double layer of silicon nitride, or a double layer of silica.

In the thin film transistor structure and the driving circuit of the AMOLED of the present invention, the shielding metal layer is configured to promote the working stability of the thin film transistor in the AMOLED driving circuit, and thus the display quality of an AMOLED display device is improved. The technical problem of the poor working stability occurs in a conventional thin film transistor and a driving circuit of an AMOLED having the thin film transistor is solved.

### BRIEF DESCRIPTION OF DRAWINGS

In order to more clearly illustrate the technical solutions in the embodiment or in the present invention, the following drawings, which are intended to be used in the description of the embodiment or of the present invention, will be briefly described. It is understood that the drawings described below are merely some embodiments of the present invention, and it will be possible to those skilled in the art to obtain other drawings according to these drawings without creative efforts.

FIG. 1 is a schematic structure of a thin film transistor structure according to one embodiment of the present invention.

FIG. 2 is a schematic structure of a thin film transistor structure according to another embodiment of the present invention.

FIG. 3 is a schematic structure of an active-matrix organic light emitting diode (AMOLED) driving circuit according to one embodiment of the present invention.

### DETAILED DESCRIPTION OF PREFERRED EMBODIMENTS

The technical solutions in the embodiment of the present invention are clearly and completely described below by referring to the accompany drawings in the embodiment of the present invention. Apparently, the described embodiments are merely a part of embodiment of the present invention rather than total embodiment. According to the embodiment of the present invention, other embodiments obtained by those of ordinary skill in the art without making creative efforts shall fall within the protection scope of the present invention.

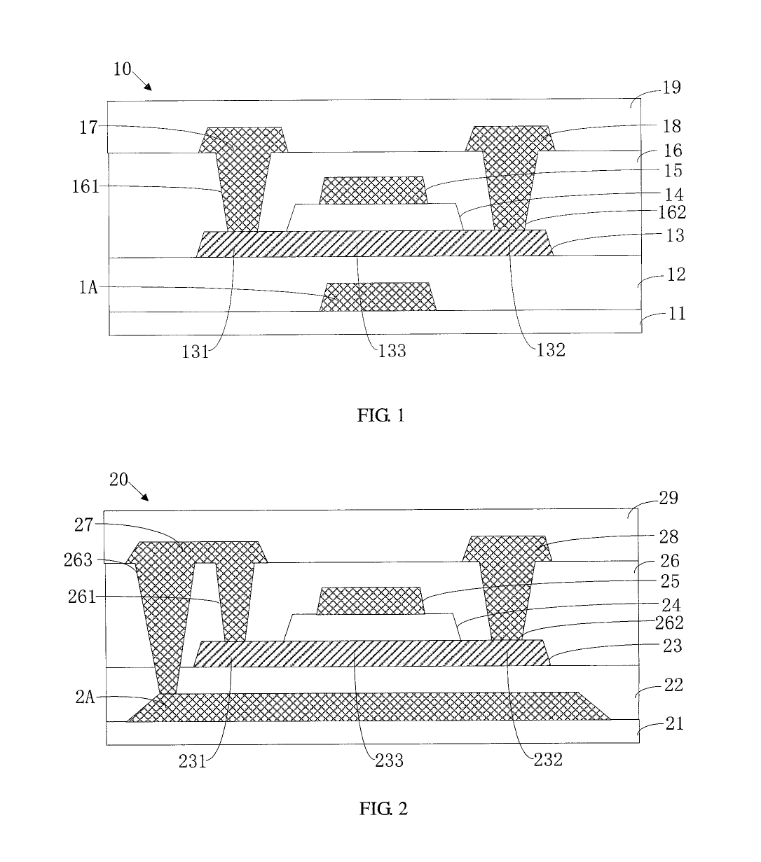

Refer to FIG. 1, FIG. 1 is a schematic structure of a thin film transistor structure according to one embodiment of the present invention. A thin film transistor structure 10 of this embodiment comprises a glass substrate 11, a buffer layer 12, a metal oxide semiconductor layer 13, a gate insulating layer 14, a gate metal layer 15, an interlayer insulating layer 16, a source metal layer 17, a drain metal layer 18, and a protective layer 19.

The buffer layer 12 is disposed on the glass substrate 11. The metal oxide semiconductor layer 13 is disposed on the buffer layer 12, and configured to define a position of an active drive area of the thin film transistor structure through the metal oxide semiconductor layer 13. The metal oxide semiconductor layer 13 comprises a source electrode area 131, a drain electrode area 132, and a channel area 133. The gate insulating layer 14 is disposed on the metal oxide semiconductor layer 13 to separate the metal oxide semiconductor layer 13 from the gate metal layer 15. The gate metal layer 15 is disposed on the gate insulating layer 14. The interlayer insulating layer 16 is disposed on the gate metal layer 15 for performing a planarization treatment on the glass substrate 11 having the gate metal layer 15. The interlayer insulating layer 16 has a source contact hole 161 and a drain contact hole 162 therein. The source metal layer 17 is disposed on the interlayer insulating layer 16, and configured to connect with the source electrode area 131 of the metal oxide semiconductor layer 13 through the source contact hole 161. The drain metal layer 18 is disposed on the interlayer insulating layer 16, and configured to connect with the drain electrode area 132 of the metal oxide semiconductor layer 13 through the drain contact hole 162. A protective layer 19 is disposed on the interlayer insulating layer 16 having the source metal layer 17 and the drain metal layer 18. A shielding metal layer 1A is disposed between the glass substrate 11 and the buffer layer 13. A projection area of the gate metal layer 15 on a plane of the glass substrate 11 covers a projection area of the shielding metal layer 1A on the plane of the glass substrate 11.

The production flow of the thin film transistor 10 according to this embodiment is described detail as below.

1. Providing a glass substrate 11, and cleaning and baking the glass substrate 11.

2. Depositing a shielding metal layer 1A on the glass substrate 11, and patterning the shielding metal layer 1A. The shielding metal layer 1A can be a molybdenum (Mo) metal layer, an aluminum (Al) metal layer, or a copper (Cu) metal layer.

3. Depositing a buffer layer 12 on the entire glass substrate 11. The buffer layer 12 can be a silica buffer layer (SiO₂) buffer layer. A thickness of the buffer layer 12 herein is preferably above 4000 Å.

4. Depositing a metal oxide semiconductor layer 13 on the buffer layer 12, and patterning the metal oxide semiconductor layer 13 to define a position of an active area of the thin film transistor structure. The metal oxide semiconductor layer 13 comprises a source electrode area 131, a drain electrode area 132, and a channel area 133. The metal oxide semiconductor layer 13 can be metal oxides such as indium gallium zinc oxide (IGZO) semiconductor layer or indium tin zinc oxide (ITZO) semiconductor layer.

5. Depositing a gate insulating layer 14 on the metal oxide semiconductor layer 13 to separate the metal oxide semiconductor layer 13 from a gate metal layer 15. The gate insulating layer 14 can be a silicon nitride (SiNₓ) layer or a silica layer (SiO₂). Specifically, the gate insulating layer 14 can be a single layer of silicon nitride, a single layer of silica, a double layer of silicon nitride, or a double layer of silica.

6. Depositing the gate metal layer 15 on the gate insulating layer 14. The gate metal layer 15 can be a molybdenum metal layer, an aluminum metal layer, or a copper metal layer. A projection area of the gate metal layer 15 on a plane of the glass substrate 11 aligns to a projection area of a shielding metal layer 1A on the plane of the glass substrate 11. The projection area of the shielding metal layer 1A on the plane of the glass substrate 11 covers a projection area of the metal oxide semiconductor layer 13 of the channel area on the plane of the glass substrate 11.

7. Depositing an interlayer insulating layer 16 on the entire glass substrate 11 for performing a planarization treatment on the glass substrate 11 having the gate metal layer 15, and patterning the interlayer insulating layer 16 to form a source contact hole 161 and a drain contact hole 162. The interlayer insulating layer 16 can be a silicon nitride (SiNₓ) layer or a silica (SiO₂) layer.

8. Depositing a source metal layer 17 and a drain metal layer 18 on the interlayer insulating layer 16. The source metal layer 17 connects with the source electrode area 131 of the metal oxide semiconductor layer 13 through the source contact hole 161; the drain metal layer 18 connects with the drain electrode area 132 of the metal oxide semiconductor layer 13 through the drain contact hole 162. The source metal layer 17 can be a molybdenum metal layer, an aluminum metal layer, or a copper metal layer; the drain metal layer 18 can be a molybdenum metal layer, an aluminum metal layer, or a copper metal layer.

9. Depositing a protective layer 19 on the entire glass substrate 11. The protective layer 19 can be a silicon nitride (SiNₓ) layer or a silica (SiO₂) layer.

In this way, the producing process of the thin film transistor structure 10 of this embodiment is completed.

When the thin film transistor structure of this embodiment is used, the effect on the working stability of the thin film transistor can be reduced because the shielding metal layer can block the light emitting to the metal oxide semiconductor layer of the channel area, so that the working stability can be improved. Meanwhile, the shielding metal layer is easy to produce and the production cost of the thin film transistor can be reduced.

Refer to FIG. 2, FIG. 2 is a schematic structure of a thin film transistor structure according to another embodiment of the present invention. The thin film transistor structure 20 of this embodiment comprises a glass substrate 21, a buffer layer 22, a metal oxide semiconductor layer 23, a gate insulating layer 24, a gate metal layer 25, an interlayer insulating layer 26, a source metal layer 27, a drain metal layer 28, and a protective layer 29.

The buffer layer 22 is disposed on the glass substrate 21. The metal oxide semiconductor layer 23 is disposed on the buffer layer 22, and configured to define a position of an active drive area of the thin film transistor structure through the metal oxide semiconductor layer 23. The metal oxide semiconductor layer 23 comprises a source electrode area 231, a drain electrode area 232, and a channel area 233. The gate insulating layer 24 is disposed on the metal oxide semiconductor layer 23 to separate the metal oxide semiconductor layer 23 from the gate metal layer 25. The gate metal layer 25 is disposed on the gate insulating layer 24. The interlayer insulating layer 26 is disposed on the gate metal layer 25 for performing a planarization treatment on the glass substrate 21 having the gate metal layer 25. The interlayer insulating layer 26 has a source contact hole 261 and a drain contact hole 262 therein. The source metal layer 27 is disposed on the interlayer insulating layer 26, and configured to connect with the source electrode area 231 of the metal oxide semiconductor layer 23 through the source contact hole 261. The drain metal layer 28 is disposed on the interlayer insulating layer 26, and configured to connect with the drain electrode area 232 of the metal oxide semiconductor layer 23 through the drain contact hole 262. A protective layer 29 is disposed on the interlayer insulating layer 26 having the source metal layer 27 and the drain metal layer 28.

A shielding metal layer 2A is disposed between the glass substrate 21 and the buffer layer 23. A projection area of the shielding metal layer 2A on a plane of the glass substrate 21 covers a projection area of the metal oxide semiconductor layer 23 on the plane of the glass substrate 21.

The interlayer insulating layer 26 has a shielding metal layer contact hole 263 passing through the interlayer insulating layer 26 and the buffer layer 22. The source metal layer 27 connects with the shielding metal layer 2A through the shielding metal layer contact hole 263.

The production flow of the thin film transistor 20 according to this embodiment is described detail as below.

1. Providing a glass substrate 21, and cleaning and baking the glass substrate 21.

2. Depositing a shielding metal layer 2A on the glass substrate 21, and patterning the shielding metal layer 2A. The shielding metal layer 2A can be a molybdenum (Mo) metal layer, an aluminum (Al) metal layer, or a copper (Cu) metal layer.

3. Depositing a buffer layer 22 on the entire glass substrate 21. The buffer layer 22 can be a silica buffer layer (SiO₂) buffer layer. A thickness of the buffer layer 22 herein is preferably above 4000 Å.

4. Depositing a metal oxide semiconductor layer 23 on the buffer layer 22, and patterning the metal oxide semiconductor layer 23 to define a position of an active area of the thin film transistor structure. The metal oxide semiconductor layer 23 comprises a source electrode area 231, a drain electrode area 232, and a channel area 233. The metal oxide semiconductor layer 23 can be metal oxides such as indium gallium zinc oxide (IGZO) semiconductor layer or indium tin zinc oxide (ITZO) semiconductor layer.

5. Depositing a gate insulating layer 24 on the metal oxide semiconductor layer 23 to separate the metal oxide semiconductor layer 23 from a gate metal layer 25. The gate insulating layer 24 can be a silicon nitride (SiNₓ) layer or a silica layer (SiO₂). Specifically, the gate insulating layer 24 can be a single layer of silicon nitride, a single layer of silica, a double layer of silicon nitride, or a double layer of silica. A projection area of the shielding metal layer 2A herein on a plane of the glass substrate 21 covers a projection area of the metal oxide semiconductor layer 23 on the plane of the glass substrate 21.

6. Depositing the gate metal layer 25 on the gate insulating layer 24. The gate metal layer 25 can be a molybdenum metal layer, an aluminum metal layer, or a copper metal layer.

7. Depositing an interlayer insulating layer 26 on the entire glass substrate 21 for performing a planarization treatment on the glass substrate 21 having the gate metal layer 25, and patterning the interlayer insulating layer 26 to form a source contact hole 261, a drain contact hole 262, and a shielding metal layer contact hole 263 passing through the interlayer insulating layer 26 and the buffer layer 22. The interlayer insulating layer 26 can be a silicon nitride (SiNₓ) layer or a silica (SiO₂) layer.

8. Depositing a source metal layer 27 and a drain metal layer 28 on the interlayer insulating layer 26. The source metal layer 27 connects with the source electrode area 231 of the metal oxide semiconductor layer 23 through the source contact hole 261; the drain metal layer 28 connects with the drain electrode area 232 of the metal oxide semiconductor layer 23 through the drain contact hole 262. The source metal layer 27 connects with the shielding metal layer 2A through the shielding metal layer contact hole 263. The source metal layer 27 can be a molybdenum metal layer, an aluminum metal layer, or a copper metal layer; the drain metal layer 28 can be a molybdenum metal layer, an aluminum metal layer, or a copper metal layer.

9. Depositing a protective layer 29 on the entire glass substrate 21. The protective layer 29 can be a silicon nitride (SiNₓ) layer or a silica (SiO₂) layer.

In this way, the producing process of the thin film transistor structure 20 of this embodiment is completed.

When the thin film transistor structure of this embodiment is used, the area of the shielding metal layer is larger so that the light emitting to the metal oxide semiconductor layer can be blocked, thereby the working stability of the thin film transistor can be further improved.

Because the area of the shielding metal layer in the thin film transistor structure of this embodiment is larger, it is possible to generate a greater parasitic capacitance. Thus, the shielding metal layer contact hole is configured to connect the source metal layer with the shielding metal layer to reduce the coupling effect of the parasitic capacitance generated by the thin film transistor structure.

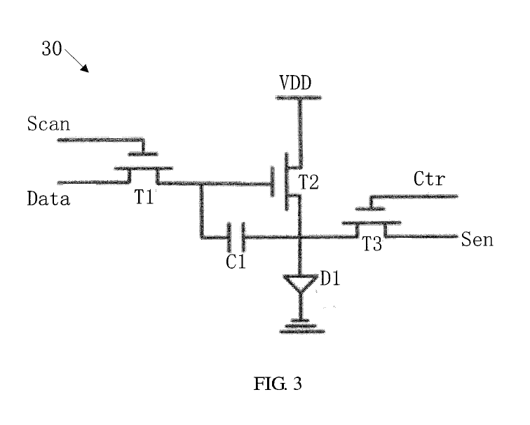

Refer to FIG. 3, FIG. 3 is a schematic structure of an active-matrix organic light emitting diode (AMOLED) driving circuit according to one embodiment of the present invention. The AMOLED driving circuit 30 in this embodiment comprises a first thin film transistor T1, a second thin film transistor T2, a third thin film transistor T3, a storage capacitor C1, and a light emitting diode D1.

An input end of the first thin film transistor T1 connects with data lines Data, a control end of the first thin film transistor T1 connects with scan lines Scan, and an output end of the first thin film transistor T1 connects with a control end of the second thin film transistor T2. An input end of the second thin film transistor T2 connects with a driving power VDD, an output end of the second thin film transistor T2 connects with a positive electrode of the light emitting diode D1. A negative electrode of the light emitting diode D1 connects with the ground. An input end of the third thin film transistor T3 connects with the output end of the second thin film transistor T2, the output end of the third thin film transistor T3 connects with an induced current check end Sen, a control end of the third thin film transistor T3 connects with a control end of the induced current check end. One end of the storage capacitor C1 connects with the control end of the second thin film transistor T2, and another end of the storage capacitor C1 connects with the output end of the second thin film transistor T2.

The first thin film transistor T1 and the third thin film transistor T3 both have the abovementioned thin film transistor structure without the shielding metal layer contact hole; the second thin film transistor T2 has the abovementioned thin film transistor structure having the shielding metal layer contact hole.

When using the AMOLED driving circuit 30 in this preferred embodiment, a scan signal is input through the scan lines Scan to the control end of the first thin film transistor T1 to control a data signal of the data lines Data to pass through the first thin film transistor T1 and output to the control end of the second thin film transistor T2.

When the second thin film transistor T2 is controlled by the data signal, the drive power VDD is controlled to drive the light emitting diode D1 to work, that is, the light emitting diode D1 changes the light intensity under the control of the data signal.

Under a control signal of a induced current control end Ctr, the third thin film transistor T3 detects the driving current of the light emitting diode D1 through the induced current check end Sen so as to realize the check and feedback control of the driving current of the light emitting diode D1.

During driving the light emitting diode D1, the second thin film transistor T2 is closest to the light emitting diode D1, and has the greatest effect on the working stability of the light emitting diode D1. Therefore, the second thin film transistor T2 uses the thin film transistor having the shielding metal layer contact hole to minimize the impact of the external light on the second thin film transistor T2.

For promoting the working stabilities of the first thin film transistor T1 and the third thin film transistor T3, the first thin film transistor T1 and the third thin film transistor T3 use the thin film transistor structure without the shielding metal layer contact hole, which is low cost and effective to reduce the impact of the external light on the channel areas of the first thin film transistor T1 and the third thin film transistor T3.

In this way, the first thin film transistor T1, the second thin film transistor T2, and the third thin film transistor T3 are provided with their respective thin film transistor structures according to their own characteristics. The AMOLED driving circuit 30 is simplified as much as possible while ensuring the normal operation of the thin film transistor to achieve the purpose of improving the stability of the AMOLED driving circuit 30 and improving the display quality of the AMOLED display device at a lower cost.

In the thin film transistor structure and the driving circuit of the AMOLED of the present invention, the shielding metal layer is configured to promote the working stability of the thin film transistor in the AMOLED driving circuit, and thus the display quality of an AMOLED display device is improved. The technical problem of the poor working stability occurs in a conventional thin film transistor and a driving circuit of an AMOLED having the thin film transistor is solved.

The present invention has been described with preferred embodiments thereof and it is understood that many changes and modifications to the described embodiments can be carried out by the skilled person in the art without departing from the scope and the spirit of the invention that is intended to be limited only by the appended claims.

1. A thin film transistor structure, comprising:
a glass substrate;
a buffer layer disposed on the glass substrate;
a metal oxide semiconductor layer disposed on the buffer layer, and configured to define a position of an active drive area of the thin film transistor structure through the metal oxide semiconductor layer, wherein the metal oxide semiconductor layer comprises a source electrode area, a drain electrode area, and a channel area;
a gate insulating layer disposed on the metal oxide semiconductor layer to separate the metal oxide semiconductor layer from a gate metal layer;
wherein the gate metal layer is disposed on the gate insulating layer;
an interlayer insulating layer disposed on the gate metal layer for performing a planarization treatment on the glass substrate having the gate metal layer, wherein the interlayer insulating layer has a source contact hole and a drain contact hole therein;
a source metal layer disposed on the interlayer insulating layer, and configured to connect with the source electrode area of the metal oxide semiconductor layer through the source contact hole;
a drain metal layer disposed on the interlayer insulating layer, and configured to connect with the drain electrode area of the metal oxide semiconductor layer through the drain contact hole; and
a protective layer disposed on the interlayer insulating layer having the source metal layer and the drain metal layer;
wherein a shielding metal layer is disposed between the glass substrate and the buffer layer, and a projection area of the gate metal layer on a plane of the glass substrate aligns to a projection area of the shielding metal layer on the plane, the projection area of the shielding metal layer on the plane of the glass substrate covers a projection area of the metal oxide semiconductor layer of the channel area on the plane of the glass substrate.

2. The thin film transistor structure according to claim 1, wherein the buffer layer has a thickness greater than 4000 Å.

3. The thin film transistor structure according to claim 1, wherein the shielding metal layer is a molybdenum metal layer, an aluminum metal layer, or a copper metal layer;
the buffer layer is a silica buffer layer;
the metal oxide semiconductor layer is an indium gallium zinc oxide metal oxide semiconductor layer or an indium tin zinc oxide metal oxide semiconductor layer;
the gate insulating layer is a silicon nitride layer or a silica layer;
the gate metal layer is a molybdenum metal layer, an aluminum metal layer, or a copper metal layer;
the source metal layer is a molybdenum metal layer, an aluminum metal layer, or a copper metal layer;
the drain metal layer is a molybdenum metal layer, an aluminum metal layer, or a copper metal layer;
the interlayer insulating layer is a silicon nitride layer or a silica layer; and
the protective layer is a silicon nitride layer or a silica layer.

4. The thin film transistor structure according to claim 3, wherein the gate insulating layer is a single layer of silicon nitride, a single layer of silica, a double layer of silicon nitride, or a double layer of silicon nitride.

5. A thin film transistor structure, comprising:
a glass substrate;
a buffer layer disposed on the glass substrate;
a metal oxide semiconductor layer disposed on the buffer layer, and configured to define a position of an active drive area of the thin film transistor structure through the metal oxide semiconductor layer, wherein the metal oxide semiconductor layer comprises a source electrode area, a drain electrode area, and a channel area;
a gate insulating layer disposed on the metal oxide semiconductor layer to separate the metal oxide semiconductor layer from a gate metal layer;
wherein the gate metal layer is disposed on the gate insulating layer;
an interlayer insulating layer disposed on the gate metal layer for performing a planarization treatment on the glass substrate having the gate metal layer, wherein the interlayer insulating layer has a source contact hole and a drain contact hole therein;
a source metal layer disposed on the interlayer insulating layer, and configured to connect with the source electrode area of the metal oxide semiconductor layer through the source contact hole;
a drain metal layer disposed on the interlayer insulating layer, and configured to connect with the drain electrode area of the metal oxide semiconductor layer through the drain contact hole; and
a protective layer disposed on the interlayer insulating layer having the source metal layer and the drain metal layer;
wherein a shielding metal layer is disposed between the glass substrate and the buffer layer, and a projection area of the shielding metal layer on the plane of the glass substrate covers a projection area of the metal oxide semiconductor layer on the plane of the glass substrate.

6. The thin film transistor structure according to claim 5, wherein the interlayer insulating layer has a shielding metal layer contact hole passing through the interlayer insulating layer and the buffer layer, and the source metal layer connects with the shielding metal layer through the shielding metal layer contact hole.

7. The thin film transistor structure according to claim 5, wherein the buffer layer has a thickness greater than 4000 Å.

8. The thin film transistor structure according to claim 5, wherein the shielding metal layer is a molybdenum metal layer, an aluminum metal layer, or a copper metal layer;
the buffer layer is a silica buffer layer;
the metal oxide semiconductor layer is an indium gallium zinc oxide metal oxide semiconductor layer or an indium tin zinc oxide metal oxide semiconductor layer;
the gate insulating layer is a silicon nitride layer or a silica layer;
the gate metal layer is a molybdenum metal layer, an aluminum metal layer, or a copper metal layer;
the source metal layer is a molybdenum metal layer, an aluminum metal layer, or a copper metal layer;
the drain metal layer is a molybdenum metal layer, an aluminum metal layer, or a copper metal layer;
the interlayer insulating layer is a silicon nitride layer or a silica layer; and
the protective layer is a silicon nitride layer or a silica layer.

9. The thin film transistor structure according to claim 8, wherein the gate insulating layer is a single layer of silicon nitride, a single layer of silica, a double layer of silicon nitride, or a double layer of silica.

10. An active-matrix organic light emitting diode (AMOLED) driving circuit, comprising a first thin film transistor, a second thin film transistor, a third thin film transistor, a storage capacitor, and a light emitting diode;
wherein the first thin film transistor has an input end connecting with data lines, a control end connecting with scan lines, and an output end connecting with a control end of the second thin film transistor;
an input end of the second thin film transistor connects with a driving power, and
an output end of the second thin film transistor connects with a positive electrode of the light emitting diode;
a negative electrode of the light emitting diode connects to the ground;
an input end of the third thin film transistor connects with the output end of the second thin film transistor, and output end of the third thin film transistor connects with an induced current check end;
one end of the storage capacitor connects with a control end of the second thin film transistor, another end of the storage capacitor connects with the output end of the second thin film transistor;
wherein each of the first thin film transistor and the third thin film transistor comprises:
a glass substrate,
a buffer layer disposed on the glass substrate;
a metal oxide semiconductor layer disposed on the buffer layer, and configured to define a position of an active drive area of the thin film transistor structure through the metal oxide semiconductor layer, wherein the metal oxide semiconductor layer comprises a source electrode area, a drain electrode area, and a channel area;
a gate insulating layer disposed on the metal oxide semiconductor layer to separate the metal oxide semiconductor layer from a gate metal layer;
wherein the gate metal layer is disposed on the gate insulating layer;
an interlayer insulating layer disposed on the gate metal layer for performing a planarization treatment on the glass substrate having the gate metal layer, wherein the interlayer insulating layer has a source contact hole and a drain contact hole therein;
a source metal layer disposed on the interlayer insulating layer, and configured to connect with the source electrode area of the metal oxide semiconductor layer through the source contact hole;
a drain metal layer disposed on the interlayer insulating layer, and configured to connect with the drain electrode area of the metal oxide semiconductor layer through the drain contact hole; and
a protective layer disposed on the interlayer insulating layer having the source metal layer and the drain metal layer;
wherein a shielding metal layer is disposed between the glass substrate and the buffer layer, and a projection area of the gate metal layer on a plane of the glass substrate aligns to a projection area of the shielding metal layer on the plane, the projection area of the shielding metal layer on the plane of the glass substrate covers a projection area of the metal oxide semiconductor layer of the channel area on the plane of the glass substrate;
the second thin film transistor comprises:
a glass substrate;
a buffer layer disposed on the glass substrate;
a metal oxide semiconductor layer disposed on the buffer layer, and configured to define a position of an active drive area of the thin film transistor structure through the metal oxide semiconductor layer, wherein the metal oxide semiconductor layer comprises a source electrode area, a drain electrode area, and a channel area;
a gate insulating layer disposed on the metal oxide semiconductor layer to separate the metal oxide semiconductor layer from a gate metal layer;
wherein the gate metal layer is disposed on the gate insulating layer;
an interlayer insulating layer disposed on the gate metal layer for performing a planarization treatment on the glass substrate having the gate metal layer, wherein the interlayer insulating layer has a source contact hole and a drain contact hole therein;
a source metal layer disposed on the interlayer insulating layer, and configured to connect with the source electrode area of the metal oxide semiconductor layer through the source contact hole;
a drain metal layer disposed on the interlayer insulating layer, and configured to connect with the drain electrode area of the metal oxide semiconductor layer through the drain contact hole; and
a protective layer disposed on the interlayer insulating layer having the source metal layer and the drain metal layer;
wherein a shielding metal layer is disposed between the glass substrate and the buffer layer, and a projection area of the shielding metal layer on the plane of the glass substrate covers a projection area of the metal oxide semiconductor layer on the plane of the glass substrate.

11. The AMOLED driving circuit according to claim 10, wherein the buffer layer has a thickness greater than 4000 Å.

12. The AMOLED driving circuit according to claim 10, wherein the shielding metal layer is a molybdenum metal layer, an aluminum metal layer, or a copper metal layer;
the buffer layer is a silica buffer layer;
the metal oxide semiconductor layer is an indium gallium zinc oxide metal oxide semiconductor layer or an indium tin zinc oxide metal oxide semiconductor layer;
the gate insulating layer is a silicon nitride layer or a silica layer;
the gate metal layer is a molybdenum metal layer, an aluminum metal layer, or a copper metal layer;
the source metal layer is a molybdenum metal layer, an aluminum metal layer, or a copper metal layer;
the drain metal layer is a molybdenum metal layer, an aluminum metal layer, or a copper metal layer;
the interlayer insulating layer is a silicon nitride layer or a silica layer; and
the protective layer a silicon nitride layer or a silica layer.

13. The AMOLED driving circuit according to claim 10, wherein the gate insulating layer is a single layer of silicon nitride, a single layer of silica, a double layer of silicon nitride, or a double layer of silica.
